(19) United States
(12) Patent Application Publication
(10) Pub. No.: US 2026/0271282 A1
(43) Pub. Date: Sep. 10, 2026

(54) SEMICONDUCTOR MEMORY DEVICE AND METHOD OF CONTROLLING SAME

(71) Applicant: Kioxia Corporation, Tokyo (JP)

(72) Inventors: Toru NAKANISHI, Kawagoe Mie (JP); Masaki KONDO, Yokkaichi Mie (JP); Fumitaka ARAI, Yokkaichi Mie (JP); Kouji MATSUO, Ama Aichi (JP)

(73) Assignee: Kioxia Corporation, Tokyo (JP)

(21) Appl. No.: 19/296,629

(22) Filed: Aug. 11, 2025

(30) Foreign Application Priority Data
Mar. 7, 2025 (JP) 2025-036785

(51) Int. Cl. H10B 41/10; G11C 5/06; G11C 16/26; G11C 16/34; H01L 23/522; H01L 23/528; H10B 41/27; H10B 41/41

(52) U.S. Cl. CPC H10B 41/10; G11C 5/063; G11C 16/26; H10B 41/27; H10B 41/41; H10W 20/42; H10W 20/43; G11C 16/3459

(57) ABSTRACT

A semiconductor memory device comprises: semiconductor layers stacked in a stacking direction; via electrodes arranged along both side surfaces of semiconductor layers; electric charge accumulating layers provided between semiconductor layers and via electrodes; and a via wiring connected to semiconductor layers. When a read operation is executed, at a first timing, via electrodes provided on a via wiring side with respect to a first via electrode are applied with a first voltage. At a second timing, the first via electrode is applied with a read voltage greater than the first voltage. A voltage of second via electrodes provided on an opposite side to the first via electrode with respect to the semiconductor layer and provided within a certain distance from the first via electrode, is maintained at the first voltage. Third via electrodes are applied with a read pass voltage greater than the read voltage.

### CROSS-REFERENCE TO RELATED APPLICATIONS

This application is based upon and claims the benefit of Japanese Patent Application No. 2025-036785, filed on Mar. 7, 2025, the entire contents of which are incorporated herein by reference.

### BACKGROUND

### Field

The present embodiments relate to semiconductor memory devices and methods of controlling same.

### Description of the Related Art

There is known a semiconductor memory device comprising: a plurality of semiconductor layers stacked in a stacking direction and extending in a first direction intersecting the stacking direction; a plurality of via electrodes which are arranged in the first direction, extend in the stacking direction, and face the plurality of semiconductor layers; and a plurality of electric charge accumulating layers provided between the plurality of semiconductor layers and the plurality of via electrodes.

### BRIEF DESCRIPTION OF THE DRAWINGS

FIG. 1 is a schematic perspective view showing a configuration of a part of a semiconductor memory device according to a first embodiment;

FIG. 2 is a schematic circuit diagram showing a configuration of a part of a memory cell array layer L_{MCA};

FIG. 3 is a schematic plan view showing a configuration of a part of the memory cell array layer L_{MCA};

FIG. 4 is a schematic cross-sectional view showing a configuration of a part of the memory cell array layer L_{MCA};

FIGS. 5A and 5B are schematic diagrams for explaining threshold voltages of a memory cell MC stored with 3 bits of data;

FIG. 6 is a schematic circuit diagram for explaining an outline of a read operation;

FIG. 7 is a flowchart for explaining an outline of a write operation;

FIG. 8 is a schematic circuit diagram for explaining an outline of a program operation;

FIG. 9 is a schematic circuit diagram for explaining an outline of a verify operation;

FIG. 10 is a schematic plan view for explaining a voltage of a facing word line WL_{O} in the read operation;

FIG. 11 is a schematic plan view for explaining a read operation according to the first embodiment;

FIG. 12 is a schematic plan view for explaining the read operation according to the first embodiment; and

FIG. 13 is a schematic plan view for explaining a read operation according to a second embodiment.

### DETAILED DESCRIPTION

A semiconductor memory device according to one embodiment comprises: a plurality of semiconductor layers stacked in a stacking direction and extending in a first direction intersecting the stacking direction; a plurality of conductive layers which are stacked in the stacking direction correspondingly to the plurality of semiconductor layers, extend in a second direction intersecting the stacking direction and the first direction, and are connected to end portions on one side in the first direction of the plurality of semiconductor layers, via an n-type semiconductor layer including an n-type impurity; a plurality of via electrodes which are arranged in the first direction along both side surfaces in the second direction of the plurality of semiconductor layers, extend in the stacking direction, and face the plurality of semiconductor layers; a plurality of electric charge accumulating layers provided between the plurality of semiconductor layers and the plurality of via electrodes; and a via wiring which extends in the stacking direction, includes a p-type semiconductor layer including a p-type impurity, and is connected to an end portion on one side or the other side in the first direction of the plurality of semiconductor layers. Moreover, in this semiconductor memory device, when a read operation is executed, at a first timing, via electrodes provided on a via wiring side with respect to a first via electrode of the plurality of via electrodes are applied with a first voltage. Moreover, at a second timing, the first via electrode is applied with a read voltage greater than the first voltage. Moreover, a voltage of a plurality of second via electrodes provided on an opposite side to the first via electrode in the second direction with respect to the semiconductor layer and provided within a range of a certain distance from the first via electrode, of the plurality of via electrodes, is maintained at the first voltage. Moreover, a plurality of third via electrodes other than the plurality of second via electrodes, of the plurality of via electrodes, are applied with a read pass voltage greater than the read voltage.

Next, semiconductor memory devices according to embodiments will be described in detail with reference to the drawings. Note that the following embodiments are merely examples, and are not shown with the intention of limiting the present invention. Moreover, the following drawings are schematic, and, for convenience of description, a part of configurations, and so on, thereof will sometimes be omitted. Moreover, portions that are common to a plurality of embodiments will be assigned with the same symbols, and descriptions thereof sometimes omitted.

Moreover, when a “semiconductor memory device” is referred to in the present specification, it will sometimes mean a memory die, and will sometimes mean a memory system including a controller die, of the likes of a memory chip, a memory card, or an SSD (Solid State Drive). Furthermore, it will sometimes mean a configuration including a host computer, of the likes of a smartphone, a tablet terminal, or a personal computer.

Moreover, in the present specification, when a first configuration is said to be “electrically connected” to a second configuration, the first configuration may be connected to the second configuration directly, or the first configuration may be connected to the second configuration via the likes of a wiring, a semiconductor member, or a transistor. For example, in the case of three transistors having been connected in series, the first transistor is still “electrically connected” to the third transistor even when the second transistor is in an OFF state.

Moreover, in the present specification, when a first configuration is said to be “connected between” a second configuration and a third configuration, it will sometimes mean that the first configuration, the second configuration, and the third configuration are connected in series, and the second configuration is connected to the third configuration via the first configuration.

Moreover, in the present specification, when a circuit, or the like, is said to “make electrically conductive” two wirings, or the like, this will sometimes mean, for example, that this circuit, or the like, includes a transistor, or the like, that this transistor, or the like, is provided in a current path between the two wirings, and that this transistor, or the like, is in an ON state.

Moreover, in the present specification, a certain direction parallel to an upper surface of a substrate will be referred to as an X-direction, a direction parallel to the upper surface of the substrate and perpendicular to the X-direction will be referred to as a Y-direction, and a direction perpendicular to the upper surface of the substrate will be referred to as a Z-direction.

Moreover, in the present specification, a direction lying along a certain plane will sometimes be referred to as a first direction, a direction intersecting the first direction along this certain plane will sometimes be referred to as a second direction, and a direction intersecting this certain plane will sometimes be referred to as a third direction. These first direction, second direction, and third direction may correspond to any of the X-direction, the Y-direction, and the Z-direction, but need not do so.

Moreover, in the present specification, expressions such as “above” or “below” will be defined with reference to the substrate. For example, an orientation of moving away from the substrate along the above-described Z-direction will be referred to as above, and an orientation of coming closer to the substrate along the Z-direction will be referred to as below. Moreover, when a lower surface or a lower end is referred to for a certain configuration, this will be assumed to mean a surface or end portion on a substrate side of this configuration, and when an upper surface or an upper end is referred to for a certain configuration, this will be assumed to mean a surface or end portion on an opposite side to the substrate of this configuration. Moreover, a surface intersecting the X-direction or the Y-direction will be referred to as a side surface, and so on.

### First Embodiment

### Configuration

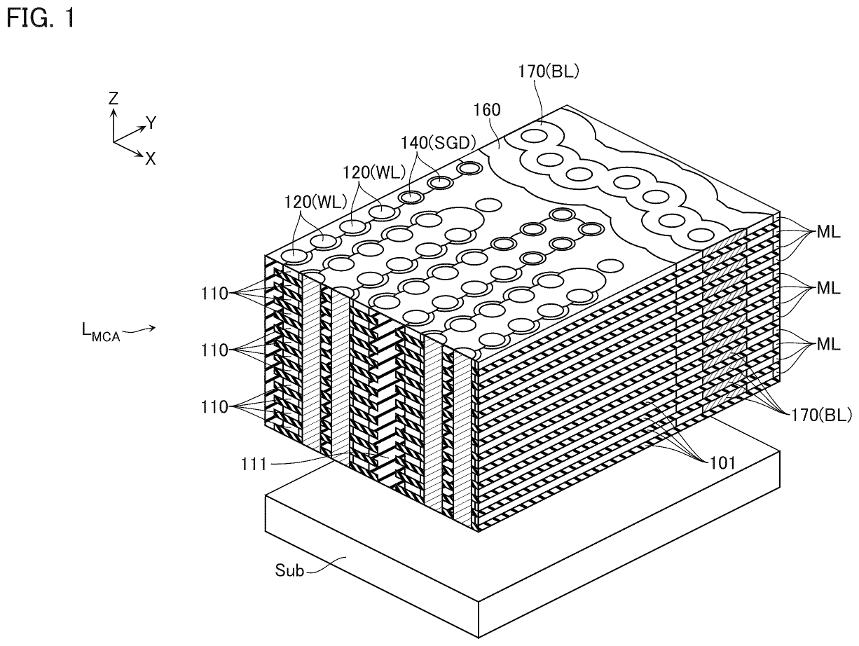

FIG. 1 is a schematic perspective view showing a configuration of a part of a semiconductor memory device according to a first embodiment. The semiconductor memory device according to the present embodiment comprises: a semiconductor substrate Sub; and a memory cell array layer L_{MCA} provided above the semiconductor substrate Sub.

The semiconductor substrate Sub includes the likes of silicon (Si) including a p-type impurity such as boron (B), for example. An upper surface of the semiconductor substrate Sub is provided with a peripheral circuit for controlling configurations in the memory cell array layer L_{MCA}.

The memory cell array layer L_{MCA} comprises a plurality of memory layers ML and the plurality of insulating layers 101 that are stacked alternately in the Z-direction. The insulating layer 101 includes the likes of silicon oxide (SiO₂), for example.

### Configuration of Memory Cell Array Layer L_{MCA}

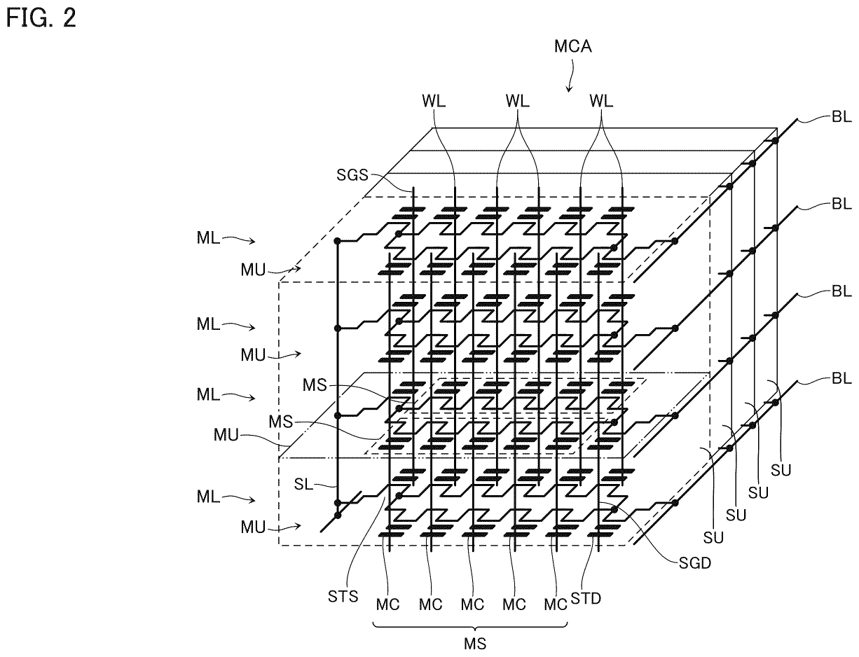

FIG. 2 is a schematic circuit diagram showing a configuration of a part of the memory cell array layer L_{MCA}.

The memory cell array layer L_{MCA} according to the present embodiment functions as a memory cell array MCA. The memory cell array MCA comprises a plurality of string units SU. The string units SU each comprise a plurality of memory units MU provided correspondingly to the plurality of memory layers ML. The plurality of memory units MU each comprise two memory strings MS. These two memory strings MS each comprise a plurality of memory cells MC (memory transistors) connected in series. One ends of these two memory strings MS are connected to a bit line BL via a common drain side select transistor STD. Moreover, the other ends of these two memory strings MS are connected to a source line SL via a common source side select transistor STS. Hereafter, the drain side select transistor STD and the source side select transistor STS will sometimes simply be referred to as select transistors STD, STS.

The memory cell MC is a field effect type transistor. The memory cell MC comprises a semiconductor layer, a gate insulating layer, and a gate electrode. The semiconductor layer functions as a channel region. The gate insulating layer includes an electric charge accumulating layer. A threshold voltage of the memory cell MC changes according to an amount of charge in the electric charge accumulating layer. The memory cell MC stores 1 bit or a plurality of bits of data. Note that the gate electrodes of the plurality of memory cells MC included in one memory unit MU are each connected with word lines WL. These word lines WL are each commonly connected to all of the memory units MU in the plurality of string units SU.

The select transistors STD, STS are each a field effect type transistor. The select transistors STD, STS each comprise a semiconductor layer, a gate insulating layer, and a gate electrode. The semiconductor layer functions as a channel region. The gate electrodes of the select transistors STD, STS are respectively connected with select gate lines SGD, SGS. The drain side select gate lines SGD are each commonly connected to all of the memory units MU in their corresponding string units SU. The source side select gate lines SGS are each commonly connected to all of the memory units MU in their corresponding string units SU.

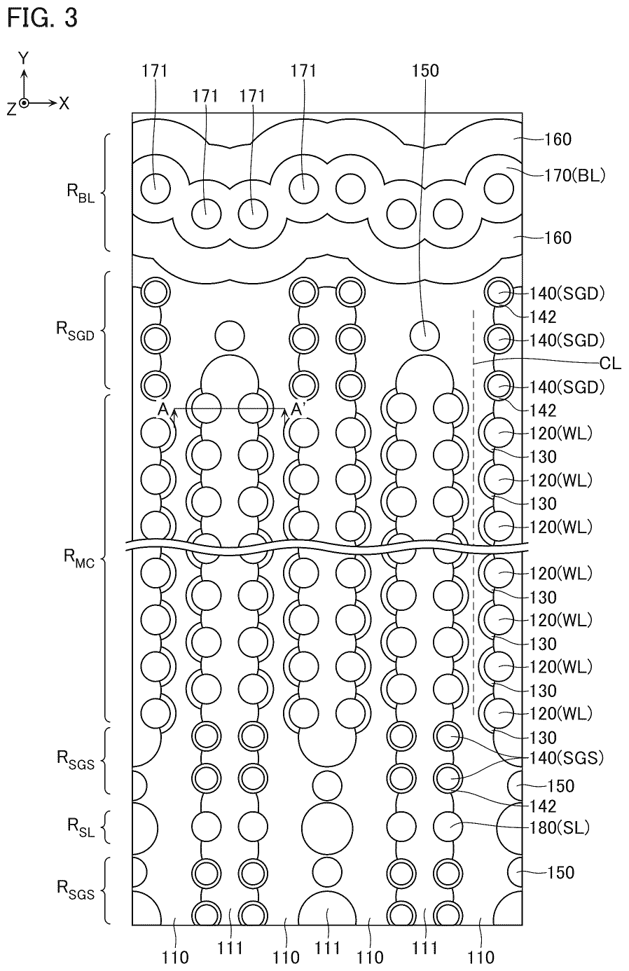

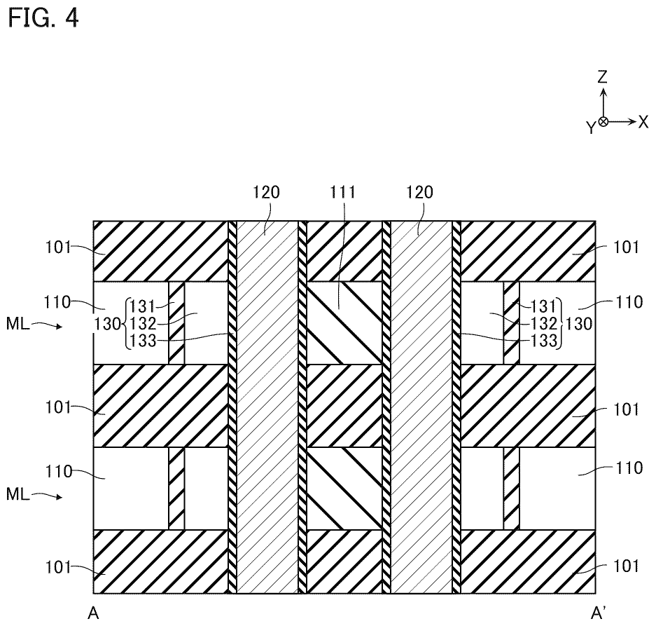

FIG. 3 is a schematic plan view showing a configuration of a part of the memory cell array layer L_{MCA}. FIG. 4 is a schematic cross-sectional view showing a configuration of a part of the memory cell array layer L_{MCA}. FIG. 4 shows a diagram in which the structure shown in FIG. 3 has been cut along the line A-A′ and viewed along a direction of the arrows.

As shown in FIG. 3, the memory cell array layer L_{MCA} comprises a bit line region R_{BL}, a select transistor region R_{SGD}, a memory cell region R_{MC}, a select transistor region R_{SGS}, and a source line region R_{SL} that are arranged in order in the Y-direction.

The memory layer ML comprises a plurality of semiconductor layers 110 arranged in the X-direction and extending in the Y-direction. These plurality of semiconductor layers 110 each extend in the Y-direction over the select transistor region R_{SGD}, the memory cell region R_{MC}, the select transistor region R_{SGS}, and the source line region R_{SL}, and reach the bit line region R_{BL}. The semiconductor layer 110 functions as channel regions of the serially-connected plurality of memory cells MC (FIG. 2) and of the select transistors STD, STS connected to these serially-connected plurality of memory cells MC, for example. The semiconductor layer 110 may include the likes of non-doped polycrystalline silicon (Si), for example.

An insulating layer 111 is provided between two semiconductor layers 110 arranged in the X-direction. The insulating layer 111 may include the likes of silicon oxide (SiO₂), for example. The insulating layer 111 extends in the Z-direction penetrating the plurality of memory layers ML, as shown in FIG. 1, for example.

The memory cell region R_{MC} is provided with a plurality of via electrodes 120 arranged in the Y-direction along side surfaces on one side and the other side in the X-direction of the semiconductor layer 110. Moreover, in the memory cell region R_{MC}, the memory layer ML comprises a plurality of gate insulating layers 130 provided between the plurality of via electrodes 120 and the semiconductor layer 110.

A part of an outer peripheral surface of the via electrode 120 faces the semiconductor layer 110 via the gate insulating layer 130, and the remaining part of the outer peripheral surface of the via electrode 120 faces the insulating layer 111. In the example illustrated, the outer peripheral surface of the via electrode 120 lies along a circle concentric with the via electrode 120. Moreover, a contact surface with the semiconductor layer 110 of the gate insulating layer 130 also lies along a circle concentric with the via electrode 120.

The via electrode 120 functions as the gate electrodes of a plurality of the memory cells MC, and as the word line WL, and so on, connected to these gate electrodes of a plurality of the memory cells MC, for example. The via electrode 120 may include a barrier conductive layer of the likes of titanium nitride (TiN), and a conductive layer of the likes of tungsten (W), for example. The via electrode 120 extends in the Z-direction penetrating the plurality of memory layers ML, as shown in FIG. 1, for example.

As shown in FIG. 4, the gate insulating layer 130 comprises, for example: a tunnel insulating layer 131 provided on a side surface in the X-direction of the semiconductor layer 110; an electric charge accumulating layer 132 provided on a side surface in the X-direction of the tunnel insulating layer 131; and a block insulating layer 133 provided on a side surface in the X-direction of the electric charge accumulating layer 132.

The tunnel insulating layer 131 may include the likes of silicon oxide (SiO₂), for example.

The electric charge accumulating layer 132 may include the likes of polycrystalline silicon (Si), for example. Moreover, this polycrystalline silicon (Si) may include an n-type impurity such as phosphorus (P) or a p-type impurity such as boron (B), or may not include these impurities.

The block insulating layer 133 may include the likes of silicon oxide (SiO₂), for example. Moreover, the block insulating layer 133 may include an insulating metal oxide film (high dielectric constant insulating film) of aluminum oxide (AlO), hafnium oxide (HfO), or others.

The select transistor region R_{SGD} (FIG. 3) is provided with: a plurality of via electrodes 140 arranged in the Y-direction along a side surface on one side in the X-direction of the semiconductor layer 110; and a via wiring 150 provided on an opposite side of a center line CL to the plurality of via electrodes 140. Moreover, in the select transistor region R_{SGD}, the memory layer ML comprises a semiconductor layer 160 connected to one ends in the Y-direction of the plurality of semiconductor layers 110.

Note that the center line CL referred to here is a center line of the semiconductor layer 110 in an XY cross section. The center line CL is an imaginary straight line extending in the Y-direction. It is possible for a position in the X-direction of the center line CL to be stipulated by a mean value of a mean value of center positions in the X-direction of a plurality of the via electrodes 120 facing a side surface on one side in the X-direction of the semiconductor layer 110, and mean value of center positions in the X-direction of a plurality of the via electrodes 120 facing a side surface on the other side in the X-direction of the semiconductor layer 110, for example.

A part of an outer peripheral surface of the via electrode 140 faces the semiconductor layer 110, and the remaining part of the outer peripheral surface of the via electrode 140 faces the insulating layer 111. A surface facing the semiconductor layer 110 of the via electrode 140 lies along a circle concentric with the via electrode 140.

The via electrode 140 in the select transistor region R_{SGD} functions as the gate electrodes of a plurality of the drain side select transistors STD, and as the drain side select gate line SGD, and so on, connected to these gate electrodes of a plurality of the drain side select transistors STD, for example. The via electrode 140 may include a barrier conductive layer of the likes of titanium nitride (TiN), and a conductive layer of the likes of tungsten (W), for example. The via electrode 140 extends in the Z-direction penetrating the plurality of memory layers ML. Moreover, the outer peripheral surface of the via electrode 140 is provided with an insulating layer 142 of the likes of silicon oxide (SiO₂) or aluminum oxide (Al₂O₃).

The via wiring 150 functions as a contact wiring for supplying positive holes to the semiconductor layer 110, for example. The via wiring 150, which includes the likes of polycrystalline silicon (Si) including a p-type impurity such as boron (B), for example, may include a semiconductor column formed in a circular column-like shape or cylindrical shape. Moreover, this semiconductor column may contact a plurality of the semiconductor layers 110 stacked in the Z-direction. The via wiring 150 extends in the Z-direction penetrating the plurality of memory layers ML.

The semiconductor layer 160, which includes a semiconductor layer of the likes of polycrystalline silicon (Si) including an n-type impurity such as phosphorus (P), for example, may contact the semiconductor layer 110.

In the bit line region R_{BL} (FIG. 3), the memory layer ML comprises a conductive layer 170. Moreover, the bit line region R_{BL} is provided with a plurality of insulating columns 171 arranged in the X-direction along the conductive layer 170.

The conductive layer 170 functions as the bit line BL (FIG. 2), for example. The conductive layer 170 may include the likes of titanium nitride (TiN), for example. The conductive layer 170 extends in the X-direction, and is electrically connected to a plurality of the semiconductor layers 110, via a plurality of the semiconductor layers 160.

The insulating column 171 may include the likes of silicon oxide (SiO₂), for example. The insulating column 171 extends in the Z-direction penetrating the plurality of memory layers ML.

The select transistor region R_{SGS} (FIG. 3) is provided with: a plurality of the via electrodes 140 arranged in the Y-direction along a side surface on one side in the X-direction of the semiconductor layer 110; and the via wiring 150 provided on an opposite side of the center line CL to the plurality of via electrodes 140.

The via electrode 140 in the select transistor region R_{SGS} functions as the gate electrodes of a plurality of the source side select transistors STS, and as the source side select gate line SGS, and so on, connected to these gate electrodes of a plurality of the source side select transistors STS, for example.

The source line region R_{SL} is provided with a via wiring 180.

The via wiring 180 functions as the source line SL, for example. The via wiring 180, which includes the likes of polycrystalline silicon (Si) including an n-type impurity such as phosphorus (P), for example, may include a semiconductor column formed in a circular column-like shape or cylindrical shape. Moreover, this semiconductor column may contact a plurality of the semiconductor layers 110 stacked in the Z-direction. The via wiring 180 extends in the Z-direction penetrating the plurality of memory layers ML.

### Threshold Voltage of Memory Cell MC

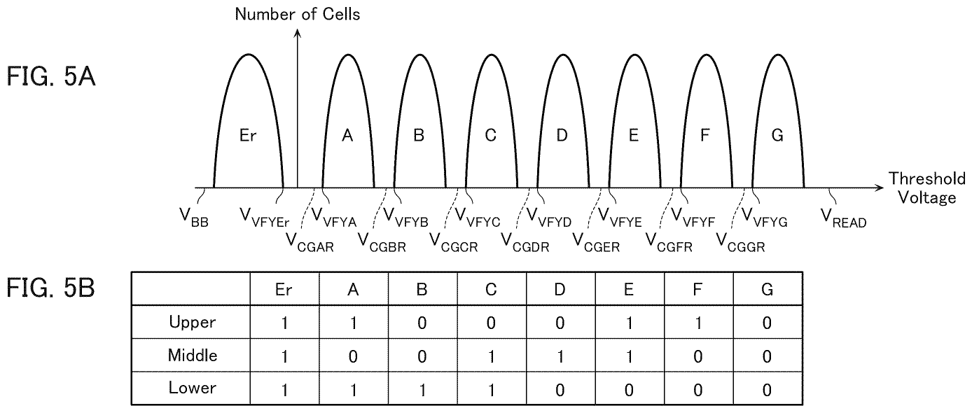

Next, threshold voltages of the memory cell MC will be described with reference to FIGS. 5A and 5B.

FIG. 5A is a schematic histogram for explaining threshold voltages of the memory cell MC stored with 3 bits of data. The horizontal axis indicates a voltage of the word line WL, and the vertical axis indicates number of memory cells MC. FIG. 5B is a table showing one example of a relationship of threshold voltages and stored data of the memory cell MC stored with 3 bits of data.

In the example of FIG. 5A, threshold voltages of the memory cell MC are controlled to eight types of states. A threshold voltage of the memory cell MC controlled to an Er state is greater than a cut-off voltage V_{BB}, but less than an erase verify voltage V_{VFYEr}. A threshold voltage of the memory cell MC controlled to an A state is greater than a verify voltage V_{VFYA}, but less than a verify voltage V_{VFYB}. A threshold voltage of the memory cell MC controlled to a B state is greater than the verify voltage V_{VFYB}, but less than a verify voltage V_{VFYC}. Likewise, threshold voltages of the memory cell MC controlled to a C state through F state are respectively greater than the verify voltage V_{VFYC} through a verify voltage V_{VFYF}, but less than a verify voltage V_{VFYD} through a verify voltage V_{VFYG}. A threshold voltage of the memory cell MC controlled to a G state is greater than the verify voltage V_{VFYG}, but less than a read pass voltage V_{READ}.

Moreover, in the example of FIG. 5A, a read voltage V_{CGAR} is set to between a threshold distribution corresponding to the Er state and a threshold distribution corresponding to the A state. Moreover, a read voltage V_{CGBR} is set to between the threshold distribution corresponding to the A state and a threshold distribution corresponding to the B state. Likewise, a read voltage V_{CGCR} through a read voltage V_{CGGR} are respectively set to between the threshold distribution corresponding to the B state and a threshold distribution corresponding to the C state through between a threshold distribution corresponding to the F state and a threshold distribution corresponding to the G state.

For example, the Er state corresponds to a lowest threshold voltage. The memory cell MC in the Er state is the memory cell MC in an erased state. The memory cell MC in the Er state is assigned with data “111”, for example.

The A state corresponds to a higher threshold voltage than the above-described threshold voltage corresponding to the Er state. The memory cell MC in the A state is assigned with data “101”, for example.

Moreover, the B state corresponds to a higher threshold voltage than the above-described a threshold voltage corresponding to the A state. The memory cell MC in the B state is assigned with data “001”, for example.

Likewise, the C state through G state in the drawings respectively correspond to higher threshold voltages than the threshold voltages corresponding to the B state through F state. The memory cells MC in these states are assigned with data “011”, “010”, “110”, “100”, “000”, for example.

In the case of assignation of the kind exemplified in FIG. 5B, lower bit data is discriminable by the single read voltage V_{CGDR}; middle bit data is discriminable by the three read voltages V_{CGAR}, V_{CGCR}, V_{CGFR}; and upper bit data is discriminable by the three read voltages V_{CGBR}, V_{CGER}, V_{CGGR}.

Note that the number of bits of data stored in the memory cell MC, the number of states, the assignation of data to each of the states, and so on, can be appropriately changed.

### Outline of Read Operation

Next, an outline of a read operation will be described. The read operation is executed on a memory cell MC that has been executed with a write operation.

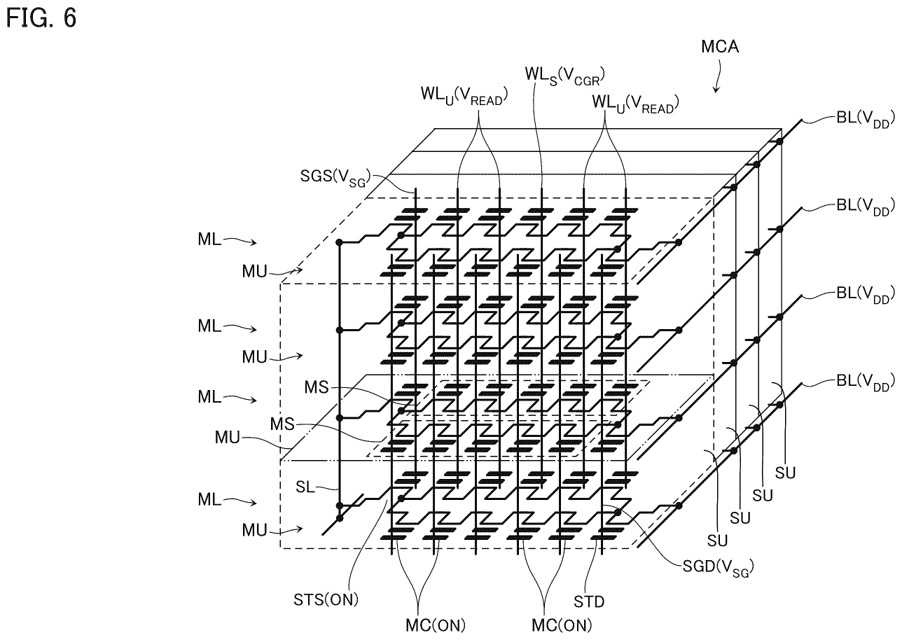

FIG. 6 is a schematic circuit diagram for explaining the outline of the read operation.

In the read operation, the plurality of memory cells MC connected to a single word line WL, in one string unit SU, represent selected memory cells MC. Hereafter, such a single word line WL will sometimes be referred to as a “selected word line WL_{S}”, and the remaining word lines WL will sometimes be referred to as “unselected word lines WL_{U}”.

In the read operation, for example, the bit line BL is applied with a voltage V_{DD}. Moreover, the source line SL is applied with a voltage V_{SRC}. The voltage V_{DD} is greater than the voltage V_{SRC}.

Moreover, in the read operation, the drain side select gate line SGD is applied with a voltage V_{SG}. A voltage V_{SG} is greater than the voltage V_{DD}. Moreover, a voltage difference between the voltage V_{SG} and the voltage V_{DD} is greater than a threshold voltage when the drain side select transistor STD is operated as an NMOS transistor. Hence, a channel of electrons will be formed in the channel region of the drain side select transistor STD, and the voltage V_{DD} will be transferred to the channel region.

Moreover, in the read operation, the source side select gate line SGS is applied with the voltage V_{SG}. Hence, a channel of electrons will be formed in the channel region of the source side select transistor STS, and the voltage V_{SRC} will be transferred to the channel region.

Moreover, in the read operation, the unselected word lines WL_{U} are applied with the read pass voltage V_{READ}. The read pass voltage V_{READ} is greater than the voltages V_{DD}, V_{SRC}. Moreover, a voltage difference between the read pass voltage V_{READ} and the voltages V_{DD}, V_{SRC} is greater than a threshold voltage when the memory cell MC is operated as an NMOS transistor, regardless of data stored in the memory cell MC. Hence, a channel of electrons will be formed in a channel region of an unselected memory cell MC, and the voltages V_{DD}, V_{SRC} will be transferred to the selected memory cell MC.

Moreover, in the read operation, the selected word line WL_{S} is applied with a read voltage V_{CGR}. The read voltage V_{CGR} is any of the read voltages V_{CGAR}, V_{CGBR}, V_{CGCR}, V_{CGDR}, V_{CGER}, V_{CGFR}, V_{CGGR} described with reference to FIGS. 5A and 5B. A voltage difference between the read voltage V_{CGR} and the voltage V_{SRC} will be greater than threshold voltage of a memory cell MC stored with some data. Therefore, the memory cell MC stored with some data will be in an ON state. Hence, a current will flow in the bit line BL connected to such a memory cell MC. On the other hand, a voltage difference between the read voltage V_{CGR} and the voltage V_{SRC} will be less than a threshold voltage of a memory cell MC stored with some data. Therefore, the memory cell MC stored with some data will be in an OFF state. Hence, a current will not flow in the bit line BL connected to such a memory cell MC.

Moreover, in the read operation, an unillustrated sense amplifier unit is used to detect whether a current is flowing in the bit line BL, or not, whereby ON state/OFF state of the memory cell MC is detected.

### Outline of Write Operation

Next, an outline of the write operation will be described. The write operation is executed on a plurality of the memory cells MC in the erased state (Er state). When the write operation is executed, these plurality of memory cells MC are controlled to any of the Er state through G state, depending on write data.

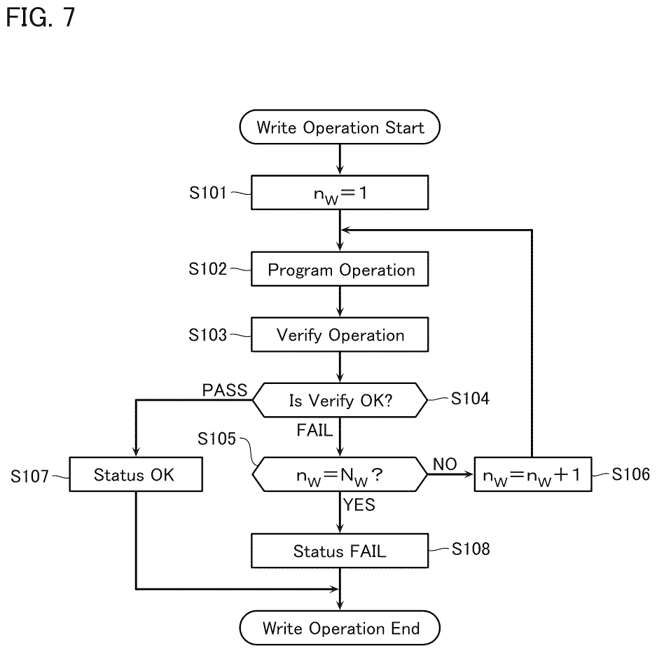

FIG. 7 is a flowchart for explaining the outline of the write operation.

In step S101, a loop count n_{W} is set to 1. The loop count n_{W} is a variable indicating the count of write loops.

In step S102, a program operation is executed. The program operation is an operation for increasing the threshold voltage of the memory cell MC by applying the selected word line WL_{S} with a program voltage, and accumulating an electric charge in the electric charge accumulating layer 132.

In step S103, a verify operation is performed. The verify operation is an operation for detecting whether the threshold voltage of the memory cell MC has reached its target value, or not, by applying the selected word line WL_{S} with a verify voltage (for example, any of the verify voltages V_{VFYA}, V_{VFYB}, V_{VFYC}, V_{VFYD}, V_{VFYE}, V_{VFYF}, V_{VFYG} described with reference to FIGS. 5A and 5B), and detecting ON state/OFF state of the memory cell MC.

In step S104, a result of the verify operation is determined. For example, in such cases as when the number of memory cells MC whose threshold voltages have not reached their target value is a certain number or more, there is determined to have been a verify FAIL, and the operation proceeds to step S105. On the other hand, in such cases as when the number of memory cells MC whose threshold voltages have not reached their target value is less than the certain number, there is determined to have been a verify PASS, and the operation proceeds to step S107.

In step S105, it is determined whether the loop count n_{W} has reached a certain count N_{W}, or not. When the loop count n_{W} has not been reached the certain count N_{W}, the operation proceeds to step S106. When the loop count n_{W} has been reached the certain count N_{W}, the operation proceeds to step S108.

In step S106, the loop count n_{W} is increased by 1, whereby the operation proceeds to step S102. Moreover, in step S106, a certain voltage ΔV is added to a program voltage V_{PGM}, for example. Hence, the program voltage V_{PGM} increases along with increase in the loop count n_{W}.

In step S107, status data to the effect that the write operation ended normally is stored in an unillustrated register, and the write operation is ended.

In step S108, status data to the effect that the write operation did not end normally is stored in the unillustrated register, and the write operation is ended.

### Outline of Program Operation

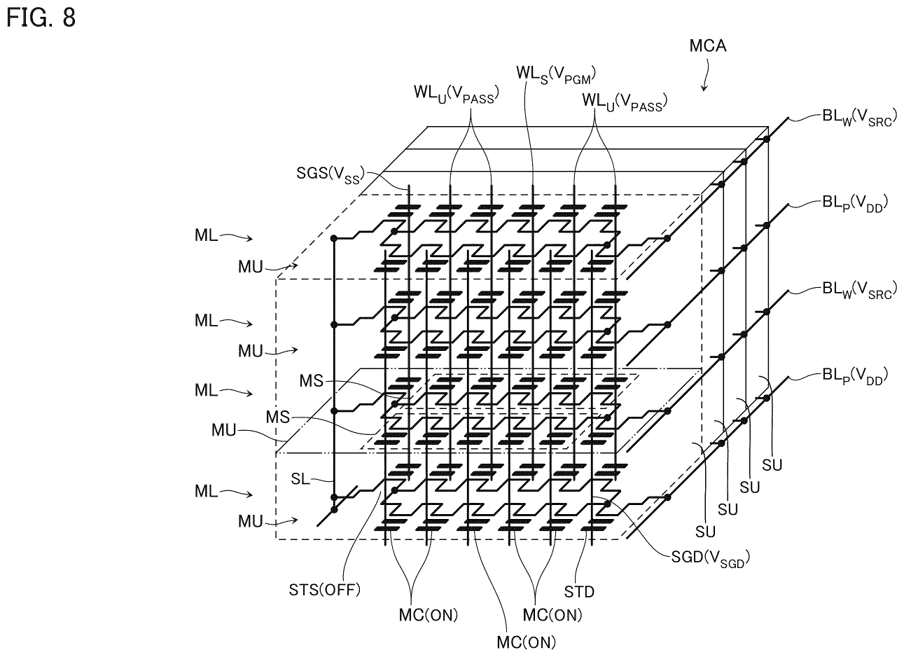

FIG. 8 is a schematic circuit diagram for explaining an outline of the program operation.

In the program operation, for example, in a part of the plurality of selected memory cells MC, an electric field will be generated between their control gate electrode and channel, and electrons in the channel of the semiconductor layer 110 will be caused to tunnel into their electric charge accumulating layer 132 (FIG. 4), thereby increasing threshold voltages of the part of the selected memory cells MC.

Hereafter, a selected memory cell MC that is to have its threshold voltage increased, of the selected memory cells MC, will be referred to as a “write memory cell MC”. Moreover, a bit line BL connected to a write memory cell MC will be referred to as a “bit line BL_{W}”. Moreover, a selected memory cell MC that is not to have its threshold voltage increased, of the selected memory cells MC, will be referred to as a “prohibit memory cell MC”. Moreover, a bit line BL connected to a prohibit memory cell MC will be referred to as a “bit line BL_{P}”.

In the program operation, for example, the bit line BL_{W} is applied with the voltage V_{SRC}. Moreover, the bit line BL_{P} is applied with the voltage V_{DD}.

Moreover, in the program operation, the drain side select gate line SGD corresponding to the string unit SU representing a target of the program operation is applied with a voltage V_{SGD}, and other drain side select gate lines SGD are applied with a voltage V_{OFF}.

The voltage V_{SGD} is greater than the voltage V_{SRC}. Moreover, a voltage difference between the voltage V_{SGD} and the voltage V_{SRC} is greater than a threshold voltage when the drain side select transistor STD is operated as an NMOS transistor. Hence, a channel of electrons will be formed in a channel region of the drain side select transistor STD connected to the bit line BL_{W}, and the voltage V_{SRC} will be transferred to the channel region.

On the other hand, a voltage difference between the voltage V_{SGD} and the voltage V_{DD} is less than a threshold voltage when the drain side select transistor STD is operated as an NMOS transistor. Hence, the drain side select transistor STD connected to the bit line BL_{P} will be in an OFF state.

The voltage V_{OFF} has a magnitude such that the drain side select transistor STD will be in an OFF state, regardless of a voltage of the bit line BL. The voltage V_{OFF} may have a negative magnitude, for example.

Moreover, in the program operation, the source line SL is applied with the voltage V_{SRC}, and the source side select gate line SGS is applied with a ground voltage V_{SS}. Now, a voltage difference between the voltage V_{SRC} and the ground voltage V_{SS} is less than a threshold voltage when the source side select transistor STS is operated as an NMOS transistor. Hence, the source side select transistor STS will be in an OFF state.

Moreover, in the program operation, the unselected word lines WL_{U} are applied with a write pass voltage V_{PASS}. The write pass voltage V_{PASS} may be greater than the read pass voltage V_{READ} described with reference to FIGS. 5A and 5B, or may be the same level as the read pass voltage V_{READ}. A voltage difference between the write pass voltage V_{PASS} and the voltage V_{SRC} is greater than a threshold voltage when the memory cell MC is operated as an NMOS transistor, regardless of data stored in the memory cell MC. Hence, a channel of electrons will be formed in a channel region of an unselected memory cell MC electrically connected to the bit line BL_{W}, and the voltage V_{SRC} will be transferred to the write memory cell MC.

Moreover, in the program operation, the selected word line WL_{S} is applied with the program voltage V_{PGM}. The program voltage V_{PGM} is greater than the write pass voltage V_{PASS}.

Now, the channel of the semiconductor layer 110 connected to the bit line BL_{W} is applied with the voltage V_{SRC}. Between such a semiconductor layer 110 and the selected word line WL_{S}, there will be generated a comparatively large electric field. This will cause electrons in the channel of the semiconductor layer 110 to tunnel into the electric charge accumulating layer 132 (FIG. 4) via the tunnel insulating layer 131 (FIG. 4). As a result, a threshold voltage of the write memory cell MC increases.

Moreover, the channel of the semiconductor layer 110 connected to the bit line BL_{P} is in an electrically floating state, and a voltage of this channel rises to about the write pass voltage V_{PASS} due to capacitive coupling with the unselected word lines WL_{U}. Between such a semiconductor layer 110 and the selected word line WL_{S}, there will only be generated a smaller electric field than the above-mentioned electric field. Consequently, electrons in the channel of the semiconductor layer 110 will not tunnel into the electric charge accumulating layer 132 (FIG. 4). Hence, a threshold voltage of the prohibit memory cell MC does not increase.

### Outline of Verify Operation

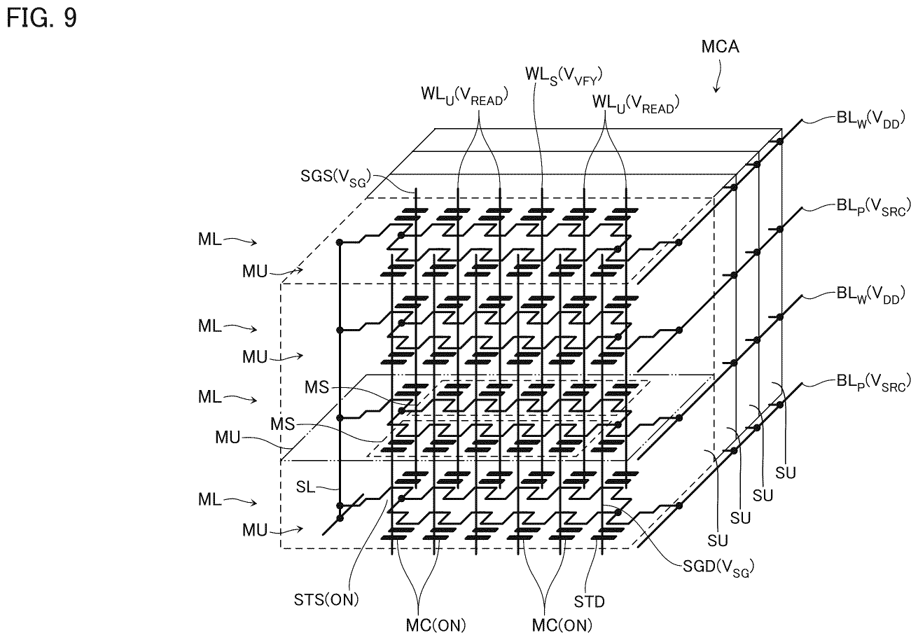

FIG. 9 is a schematic circuit diagram for explaining an outline of the verify operation.

The verify operation is basically executed similarly to the read operation.

However, in the verify operation, there is no need for a threshold voltage of the prohibit memory cell MC to be confirmed. Hence, for example, the bit line BL_{W} may be applied with the voltage V_{DD}, and the bit line BL_{P} may be applied with the voltage V_{SRC}.

Moreover, in the verify operation, the selected word line WL_{S} is applied with a verify voltage V_{VFY}, not the read voltage V_{CGR}. The verify voltage V_{VFY} is any of the verify voltages V_{VFYA}, V_{VFYB}, V_{VFYC}, V_{VFYD}, V_{VFYE}, V_{VFYF}, V_{VFYG} described with reference to FIGS. 5A and 5B. A voltage difference between the verify voltage V_{VFY} and the voltage V_{SRC} is a target value of a threshold voltage of the write memory cell MC. Therefore, a write memory cell MC whose threshold voltage has not reached the target value will be in an ON state. Hence, a current will flow in the bit line BL_{W} connected to such a write memory cell MC. On the other hand, a write memory cell MC whose threshold voltage has reached the target value will be in an OFF state. Hence, a current will not flow in the bit line BL_{W} connected to such a write memory cell MC.

### Voltage of Facing Word Lines WL_{O} in Read Operation

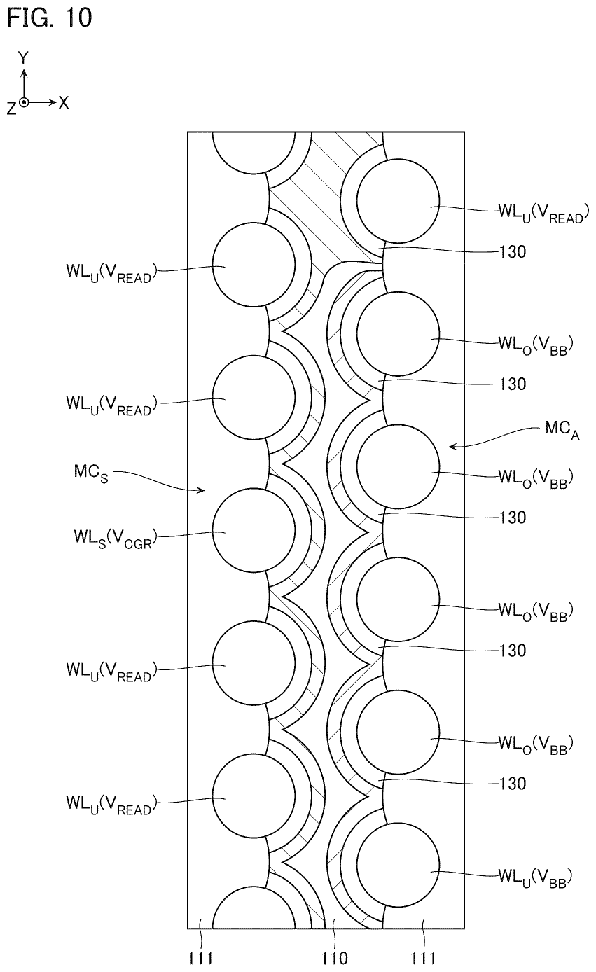

FIG. 10 is a schematic plan view for explaining a voltage of facing word lines WL_{O} in the read operation.

In the following description, the plurality of word lines WL provided on an opposite side to the selected word line WL_{S} in the X-direction with respect to the semiconductor layer 110 and provided within a range of a certain distance from the selected word line WL_{S}, of the plurality of unselected word lines WL_{U} will sometimes be referred to as “facing word lines WL_{O}”, and be distinguished from other unselected word lines WL_{U}. Moreover, a memory cell MC connected to a facing word line WL_{O} will sometimes be referred to as a “facing memory cell MC”.

In the semiconductor memory device according to the present embodiment, for example, when the facing word line WL_{O} is applied with the read pass voltage V_{READ}, a current will flow between the bit line BL and the source line SL regardless of a threshold voltage of the selected memory cell MC, and it will be impossible for data stored in the selected memory cell MC to be normally read. Hence, in the read operation, the facing word line WL_{O} is applied with the cut-off voltage V_{BB} described with reference to FIGS. 5A and 5B. The cut-off voltage V_{BB} is less than a threshold voltage when the memory cell MC is operated as an NMOS transistor, regardless of data stored in the memory cell MC. Hence, a channel of electrons will not be formed in a channel region of the facing memory cell MC.

Now, in the present embodiment, the write operation is executed in order from those memory cells MC provided on a source line SL side, of the plurality of memory cells MC included in one memory unit MU. In the following description, a memory cell MC undergoing execution of the write operation one after the selected memory cell MC (selected memory cell MC_{S} in the drawings) will sometimes be referred to as a “memory cell MC_{A}”. The memory cell MC_{A} is one of the two memory cells MC most closely adjacent to the selected memory cell MC_{S}. At a timepoint when the write operation of the selected memory cell MC_{S} is executed, a threshold voltage of the memory cell MC_{A} is the Er state described with reference to FIG. 5A. On the other hand, at a timepoint when the write operation corresponding to the memory unit MU has ended, the threshold voltage of the memory cell MC_{A} will be controlled to any of the Er state through G state.

Now, a voltage of the channel region of the selected memory cell MC_{S} fluctuates according to a voltage of the channel region of the facing memory cell MC. Consequently, there is a risk that a threshold voltage of the selected memory cell MC_{S} will differ between when the write operation is executed (when the verify operation is executed) and when the read operation is executed. As a result, there is a risk that data of the selected memory cell MC_{S} will be mistakenly read.

In order to suppress occurrence of such a phenomenon, it is conceivable, for example, for the plurality of facing word lines WL_{O} and the plurality of unselected word lines WL_{U} provided more to the source line SL side than these facing word lines WL_{O}, of those word lines WL provided on an opposite side to the selected word line WL_{S} in the X-direction with respect to the semiconductor layer 110, of the plurality of word lines WL, to be applied with the cut-off voltage V_{BB}, as in FIG. 10. Such a method makes it possible for a channel of positive holes to be formed in the channel region of memory cells MC connected to these facing word lines WL_{O} and unselected word lines WL_{U}, and for this channel of positive holes to be made electrically conductive with the via wiring 150, thereby fixing a voltage of the channel. It is hence made possible to configure so that values of a voltage of the channel region of the facing memory cell MC will be close at times when the verify operation is executed and when the read operation is executed.

However, at a time of executing the write operation, there are included among the memory cells MC provided more to the source line SL side than the selected memory cell MC_{S} memory cells MC whose threshold voltage is the Er state. A threshold voltage (difference between a source voltage and a gate voltage) to operate such a memory cell MC as a PMOS transistor is comparatively large. Furthermore, in the example of FIG. 10, all of those word lines WL provided on a selected word line WL_{S} side in the X-direction with respect to the semiconductor layer 110, of the plurality of word lines WL are being applied with the read pass voltage V_{READ}. Therefore, sometimes, a voltage of the entire semiconductor layer 110 cannot be suitably lowered, and a channel of positive holes cannot be suitably formed. Hence, sometimes, a voltage of the channel region of the facing memory cell MC cannot be suitably fixed, and a threshold voltage of the selected memory cell MC_{S}, too, fluctuates.

### Read Operation According to First Embodiment

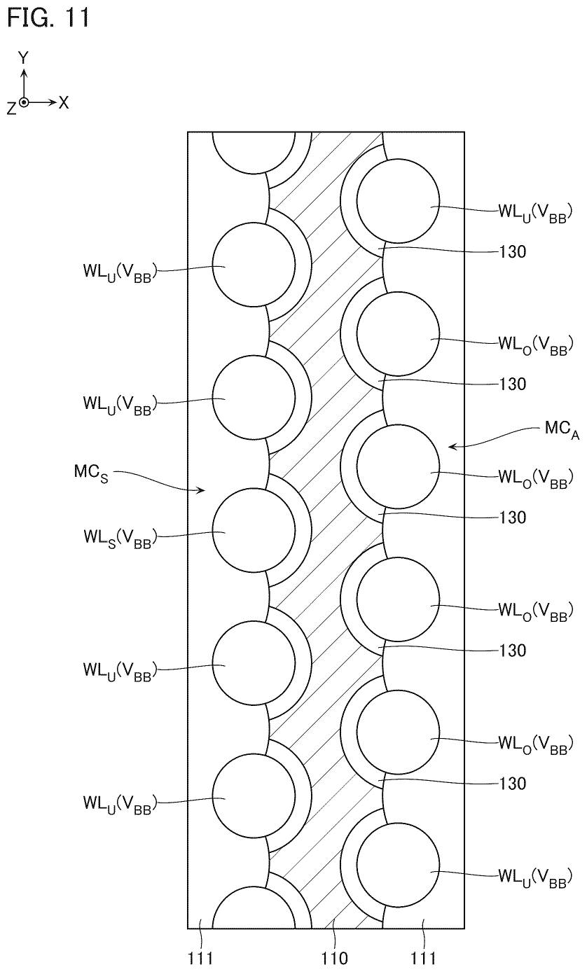

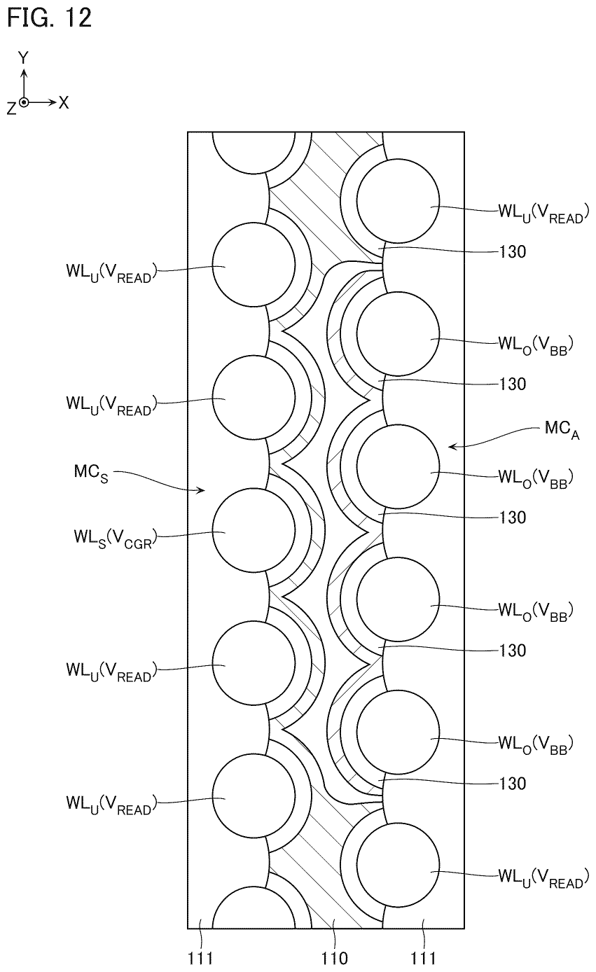

FIGS. 11 and 12 are schematic plan views for explaining a read operation according to the first embodiment.

At a certain timing of the read operation according to the first embodiment, as shown in FIG. 11, all of the word lines WL are applied with the cut-off voltage V_{BB}. That is, at a timing shown in FIG. 11, not only those word lines WL provided on one side in the X-direction with respect to the semiconductor layer 110, but also those word lines WL provided on the other side in the X-direction with respect to the semiconductor layer 110, of the plurality of word lines WL are applied with the cut-off voltage V_{BB}. As a result, a channel of positive holes is formed in the entire semiconductor layer 110, and this channel of positive holes is electrically conductive with the via wiring 150. Moreover, positive holes are supplied from the via wiring 150. At this time, a voltage of this channel of positive holes will become equal to a voltage of the via wiring 150, regardless of the threshold voltage of the memory cell MC_{A}.

Next, at a certain timing of the read operation, as shown in FIG. 12, in a state where a voltage of the facing word lines WL_{O} has been maintained at the cut-off voltage V_{BB}, the unselected word lines WL_{U} other than the facing word lines WL_{O} are applied with the read pass voltage V_{READ}. Consequently, the channel of positive holes formed in the channel region of the facing memory cells will be electrically isolated from the via wiring 150, and be in a floating state.

Moreover, the selected word line WL_{S} is applied with the read voltage V_{CGR}. As a result, as described with reference to FIG. 6, the memory cell MC stored with some data will be in an ON state, and a current will flow in the bit line BL connected to such a memory cell MC. On the other hand, the memory cell MC stored with some data will be in an OFF state, and a current will not flow in the bit line BL connected to such a memory cell MC.

Note that as mentioned above, the verify operation is executed substantially similarly to the read operation. Hence, in the verify operation, too, the operation described with reference to FIG. 11 is executed. Moreover, the facing word lines WL_{O} and the unselected word lines WL_{U} are applied with the voltages described with reference to FIG. 12.

In such a method, as described with reference to FIG. 11, all of the word lines WL are applied with the cut-off voltage V_{BB} at a certain timing in the read operation, hence it is made possible for a channel of positive holes to be suitably formed in the entire semiconductor layer 110. Moreover, as described with reference to FIG. 12, at a certain timing in the read operation, this channel of positive holes is electrically isolated from the via wiring 150. This makes it possible for a voltage of the channel region of the memory cell MC_{A} to be set unified to about the same degree of magnitude at times when the read operation is executed and when the verify operation is executed. As a result, it can be suppressed that data of the selected memory cell MC_{S} is mistakenly read.

Note that in the operation described with reference to FIG. 11, it is only required that a channel of positive holes can be formed in the channel region of the facing memory cell MC, and that this channel can be made electrically conductive with at least one of the two via wirings 150 provided on a bit line BL side and the source line SL side. Hence, it is not necessarily required for all of the word lines WL to be applied with the cut-off voltage V_{BB}.

For example, as mentioned above, in the present embodiment, the write operation is executed in order from those memory cells MC provided on the source line SL side, of the plurality of memory cells MC included in one memory unit MU. Hence, at a stage of the verify operation, it is comparatively difficult for a channel of positive holes to be formed in a channel region of those unselected memory cells MC provided more to the bit line BL side than the selected memory cell MC_{S}, of the plurality of unselected memory cells MC. In such a case, for example, in the operation described with reference to FIG. 11, the selected word line WL_{S}, the facing word lines WL_{O}, and all of the unselected word lines WL_{U} provided on the source line SL side with respect to the selected word line WL_{S} may be applied with the cut-off voltage V_{BB}, and the thereby formed channel of positive holes may be made electrically conductive with solely the via wiring 150 provided on a source line SL side. That is, the unselected word lines WL_{U} provided on the bit line BL side with respect to the selected word line WL_{S} may be applied with a different voltage from the cut-off voltage V_{BB}.

On the other hand, it is possible too for the write operation to be executed in order from those memory cells MC provided on the bit line BL side, of the plurality of memory cells MC included in one memory unit MU. In such a case, at a stage of the verify operation, it is comparatively difficult for a channel of positive holes to be formed in a channel region of those unselected memory cells MC provided more to the source line SL side than the selected memory cell MC_{S}, of the plurality of unselected memory cells MC. In such a case, for example, in the operation described with reference to FIG. 11, the selected word line WL_{S}, the facing word lines WL_{O}, and all of the unselected word lines WL_{U} provided on the bit line BL side with respect to the selected word line WL_{S} may be applied with the cut-off voltage V_{BB}, and the thereby formed channel of positive holes may be made electrically conductive with solely the via wiring 150 provided on the bit line BL side. That is, the unselected word lines WL_{U} provided on the source line SL side with respect to the selected word line WL_{S} may be applied with a different voltage from the cut-off voltage V_{BB}.

### Second Embodiment

Next, a semiconductor memory device according to a second embodiment will be described. In the following description, portions similar to in the first embodiment will be assigned with the same symbols as in the first embodiment, and descriptions thereof omitted.

As mentioned above, in the first embodiment, the write operation is executed in order from those memory cells MC provided on the source line SL side, of the plurality of memory cells MC included in one memory unit MU. Hence, in an operation corresponding to FIG. 12 of the verify operation, sometimes, a channel of positive holes cannot be suitably formed in the channel region of the memory cell MC_{A}.

Accordingly, in the second embodiment, it is by a channel of electrons being formed in the channel region of the memory cell MC_{A} undergoing execution of the write operation after the selected memory cell MC, and the channel of electrons being made electrically conductive with the bit line BL, that a voltage of the channel region of the memory cell MC_{A} is fixed.

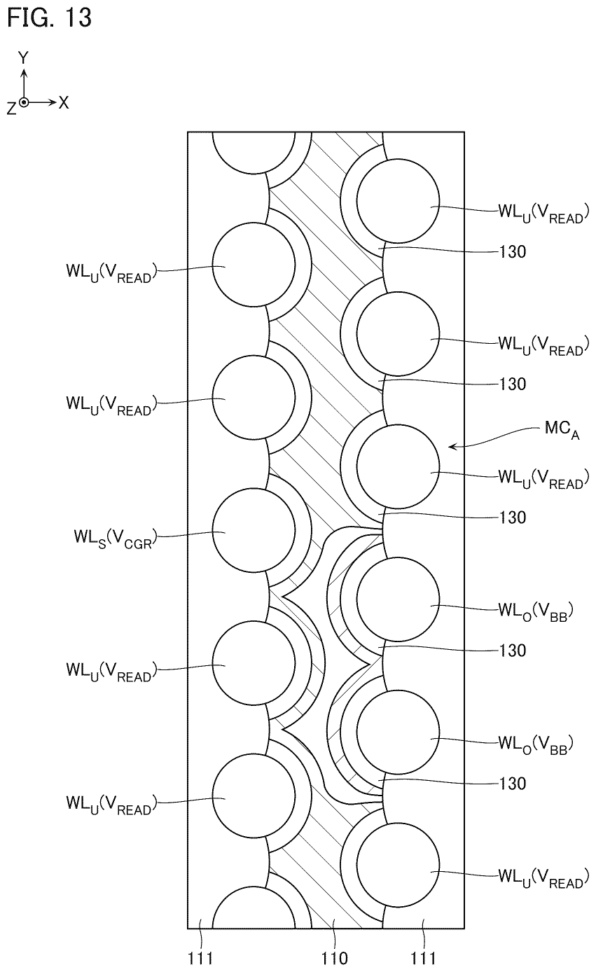

FIG. 13 is a schematic plan view for explaining a read operation according to the second embodiment. FIG. 13 shows voltages applied to the word lines WL at a timing corresponding to FIG. 12 of the read operation according to the present embodiment.

The read operation according to the second embodiment is basically executed similarly to the read operation according to the first embodiment.

However, in the first embodiment, all four of the plurality of word lines WL provided on an opposite side to the selected word line WL_{S} in the X-direction with respect to the semiconductor layer 110 and provided within a range of a certain distance from the selected word line WL_{S}, are assumed to be facing word lines WL_{O}. Moreover, voltages of these four facing word lines WL_{O} are maintained at the cut-off voltage V_{BB} from the timing described with reference to FIG. 11 to the timing described with reference to FIG. 12.

On the other hand, in the second embodiment, of the plurality of word lines WL, that is, the four word lines WL provided on an opposite side to the selected word line WL_{S} in the X-direction with respect to the semiconductor layer 110 and provided within a range of a certain distance from the selected word line WL_{S}, only the two provided on the source line SL side with respect to the selected word line WL_{S} are assumed to be facing word lines WL_{O}, while the two provided on the bit line BL side with respect to the selected word line WL_{S} are assumed to be unselected word lines WL_{U}. Moreover, voltages of these two facing word lines WL_{O} are maintained at the cut-off voltage V_{BB} from the timing described with reference to FIG. 11 to a timing corresponding to FIG. 13. Moreover, the two word lines WL assumed to be unselected word lines WL_{U} are applied with the read pass voltage V_{READ}, similarly to the other unselected word lines WL_{U}.

Note that in the second embodiment, too, similarly to in the first embodiment, the verify operation is executed substantially similarly to the read operation. Hence, in the verify operation, too, the operation described with reference to FIG. 11 is executed. Moreover, the facing word lines WL_{O} and the unselected word lines WL_{U} are applied with the voltages described with reference to FIG. 13.

Such a method makes it possible for a voltage of the channel region of the memory cell MC_{A} undergoing execution of the write operation after the selected memory cell MC, to be more easily fixed in the read operation and verify operation. Hence, a more suitably operating semiconductor memory device can be provided.

Note that the word lines WL applied with the cut-off voltage V_{BB} in the operation described with reference to FIG. 11 are appropriately adjustable, similarly to in the first embodiment.

Moreover, in the present embodiment, too, similarly to in the first embodiment, it is possible too for the write operation to be executed in order from those memory cells MC provided on the bit line BL side, of the plurality of memory cells MC included in one memory unit MU. In such a case, for example, of the plurality of word lines WL, that is, the four word lines WL provided on an opposite side to the selected word line WL_{S} in the X-direction with respect to the semiconductor layer 110 and provided within a range of a certain distance from the selected word line WL_{S}, the two provided on the bit line BL side with respect to the selected word line WL_{S} may be assumed to be facing word lines WL_{O}, while the two provided on the source line SL side with respect to the selected word line WL_{S} may be assumed to be unselected word lines WL_{U}.

### Other Embodiments

In the first embodiment, an example has been shown where four facing word lines WL_{O} are provided in the read operation and the verify operation. However, there may be three or fewer facing word lines WL_{O}, or there may be five or more facing word lines WL_{O}. Similarly, in the second embodiment, an example has been shown where two facing word lines WL_{O} are provided in the read operation and the verify operation. However, there may be one facing word line WL_{O}, or there may be three or more facing word lines WL_{O}.

Moreover, in the first embodiment and the second embodiment, the one or the plurality of word lines WL adjacent to the facing word lines WL_{O}, of those unselected word lines WL_{U} provided on an opposite side to the selected word line WL_{S} in the X-direction with respect to the semiconductor layer 110, of the plurality of unselected word lines WL_{U}, may be applied with another voltage having a magnitude between the cut-off voltage V_{BB} and the read pass voltage V_{READ}.

### Others

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor memory device comprising:
a plurality of semiconductor layers stacked in a stacking direction and extending in a first direction intersecting the stacking direction;
a plurality of conductive layers which are stacked in the stacking direction correspondingly to the plurality of semiconductor layers, extend in a second direction intersecting the stacking direction and the first direction, and are connected to end portions on one side in the first direction of the plurality of semiconductor layers, via an n-type semiconductor layer including an n-type impurity;
a plurality of via electrodes which are arranged in the first direction along both side surfaces in the second direction of the plurality of semiconductor layers, extend in the stacking direction, and face the plurality of semiconductor layers;
a plurality of electric charge accumulating layers provided between the plurality of semiconductor layers and the plurality of via electrodes; and
a via wiring which extends in the stacking direction, includes a p-type semiconductor layer including a p-type impurity, and is connected to an end portion on one side or the other side in the first direction of the plurality of semiconductor layers, wherein
when a read operation is executed,
at a first timing, via electrodes provided on a via wiring side with respect to a first via electrode, of the plurality of via electrodes, are applied with a first voltage, and
at a second timing,
the first via electrode is applied with a read voltage greater than the first voltage,
a voltage of a plurality of second via electrodes provided on an opposite side to the first via electrode in the second direction with respect to the semiconductor layer and provided within a range of a certain distance from the first via electrode, of the plurality of via electrodes, is maintained at the first voltage, and
a plurality of third via electrodes other than the plurality of second via electrodes, of the plurality of via electrodes, are applied with a read pass voltage greater than the read voltage.

2. The semiconductor memory device according to claim 1, wherein
the plurality of third via electrodes include:
a plurality of via electrodes provided on a plurality of conductive layers side with respect to the first via electrode, of via electrodes provided on a first via electrode side in the second direction with respect to the semiconductor layer, of the plurality of via electrodes;
a plurality of via electrodes provided on an opposite side to the plurality of conductive layers with respect to the first via electrode, of the via electrodes provided on the first via electrode side in the second direction with respect to the semiconductor layer, of the plurality of via electrodes; and
at least one via electrode provided on a via wiring side with respect to the plurality of second via electrodes, of via electrodes provided on an opposite side to the first via electrode in the second direction with respect to the semiconductor layer, of the plurality of via electrodes.

3. The semiconductor memory device according to claim 2, wherein
the plurality of third via electrodes include:
a plurality of via electrodes provided on a plurality of conductive layers side with respect to the plurality of second via electrodes, of the via electrodes provided on the opposite side to the first via electrode in the second direction with respect to the semiconductor layer, of the plurality of via electrodes; and
a plurality of via electrodes provided on an opposite side to the plurality of conductive layers with respect to the plurality of second via electrodes, of the via electrodes provided on the opposite side to the first via electrode in the second direction with respect to the semiconductor layer, of the plurality of via electrodes.

4. The semiconductor memory device according to claim 1, wherein
positions of via electrodes provided on one side in the second direction with respect to the semiconductor layer, of the plurality of via electrodes each differ from positions of via electrodes provided on the other side in the second direction with respect to the semiconductor layer, of the plurality of via electrodes, and
the plurality of second via electrodes include two via electrodes that are provided on an opposite side to the first via electrode in the second direction with respect to the semiconductor layer, and are closest to the first via electrode.

5. The semiconductor memory device according to claim 1, wherein
positions of via electrodes provided on one side in the second direction with respect to the semiconductor layer, of the plurality of via electrodes each differ from positions of via electrodes provided on the other side in the second direction with respect to the semiconductor layer, of the plurality of via electrodes,
the plurality of second via electrodes include one being the one provided more to a via wiring side than the first via electrode, of two via electrodes that are provided on an opposite side to the first via electrode in the second direction with respect to the semiconductor layer, and are closest to the first via electrode, and
the plurality of third via electrodes include the other being the one provided more to a plurality of conductive layers side than the first via electrode, of the two via electrodes.

6. The semiconductor memory device according to claim 1, wherein
a plurality of the plurality of semiconductor layers are provided to be arranged in the second direction.

7. The semiconductor memory device according to claim 1, comprising
a plurality of via insulating layers which are arranged in the second direction along the plurality of conductive layers, and extend in the stacking direction penetrating the plurality of conductive layers.

8. The semiconductor memory device according to claim 1, comprising
a plurality of memory cells each including: a part of one of the plurality of semiconductor layers; one of the plurality of electric charge accumulating layers; and a part of one of the plurality of via electrodes, wherein
the plurality of memory cells are each configured to store a plurality of bits of data.

9. The semiconductor memory device according to claim 8, wherein
a write operation is performed in order from a memory cell which is far from the plurality of conductive layers, of the plurality of memory cells.

10. The semiconductor memory device according to claim 1, wherein
the plurality of semiconductor layers include polycrystalline silicon (Si).

11. The semiconductor memory device according to claim 1, wherein
the via wiring includes polycrystalline silicon (Si).

12. A method of controlling a semiconductor memory device, the semiconductor memory device comprising:
a plurality of semiconductor layers stacked in a stacking direction and extending in a first direction intersecting the stacking direction;
a plurality of conductive layers which are stacked in the stacking direction correspondingly to the plurality of semiconductor layers, extend in a second direction intersecting the stacking direction and the first direction, and are connected to end portions on one side in the first direction of the plurality of semiconductor layers, via an n-type semiconductor layer including an n-type impurity;
a plurality of via electrodes which are arranged in the first direction along both side surfaces in the second direction of the plurality of semiconductor layers, extend in the stacking direction, and face the plurality of semiconductor layers;
a plurality of electric charge accumulating layers provided between the plurality of semiconductor layers and the plurality of via electrodes; and
a via wiring which extends in the stacking direction, includes a p-type semiconductor layer including a p-type impurity, and is connected to an end portion on one side or the other side in the first direction of the plurality of semiconductor layers, wherein
the method of controlling the semiconductor memory device is one in which
when a read operation is executed,
at a first timing, via electrodes provided on a via wiring side with respect to a first via electrode of the plurality of via electrodes are applied with a first voltage, and
at a second timing,
the first via electrode is applied with a read voltage greater than the first voltage,
a voltage of a plurality of second via electrodes provided on an opposite side to the first via electrode in the second direction with respect to the semiconductor layer and provided within a range of a certain distance from the first via electrode, of the plurality of via electrodes, is maintained at the first voltage, and
a plurality of third via electrodes other than the plurality of second via electrodes, of the plurality of via electrodes, are applied with a read pass voltage greater than the read voltage.

13. The method of controlling the semiconductor memory device according to claim 12, wherein
the plurality of third via electrodes include:
a plurality of via electrodes provided on a plurality of conductive layers side with respect to the first via electrode, of via electrodes provided on a first via electrode side in the second direction with respect to the semiconductor layer, of the plurality of via electrodes;
a plurality of via electrodes provided on an opposite side to the plurality of conductive layers with respect to the first via electrode, of the via electrodes provided on the first via electrode side in the second direction with respect to the semiconductor layer, of the plurality of via electrodes; and
at least one via electrode provided on a via wiring side with respect to the plurality of second via electrodes, of via electrodes provided on an opposite side to the first via electrode in the second direction with respect to the semiconductor layer, of the plurality of via electrodes.

14. The method of controlling the semiconductor memory device according to claim 13, wherein
the plurality of third via electrodes include:
a plurality of via electrodes provided on a plurality of conductive layers side with respect to the plurality of second via electrodes, of via electrodes provided on an opposite side to the first via electrode in the second direction with respect to the semiconductor layer, of the plurality of via electrodes; and
a plurality of via electrodes provided on an opposite side to the plurality of conductive layers with respect to the plurality of second via electrodes, of the via electrodes provided on the opposite side to the first via electrode in the second direction with respect to the semiconductor layer, of the plurality of via electrodes.

15. The method of controlling the semiconductor memory device according to claim 12, wherein
positions of via electrodes provided on one side in the second direction with respect to the semiconductor layer, of the plurality of via electrodes each differ from positions of via electrodes provided on the other side in the second direction with respect to the semiconductor layer, of the plurality of via electrodes, and
the plurality of second via electrodes include two via electrodes that are provided on an opposite side to the first via electrode in the second direction with respect to the semiconductor layer, and are closest to the first via electrode.

16. The method of controlling the semiconductor memory device according to claim 12, wherein
positions of via electrodes provided on one side in the second direction with respect to the semiconductor layer, of the plurality of via electrodes each differ from positions of via electrodes provided on the other side in the second direction with respect to the semiconductor layer, of the plurality of via electrodes,
the plurality of second via electrodes include one being the one provided more to a via wiring side than the first via electrode, of two via electrodes that are provided on an opposite side to the first via electrode in the second direction with respect to the semiconductor layer, and are closest to the first via electrode, and
the plurality of third via electrodes include the other being the one provided more to a plurality of conductive layers side than the first via electrode, of the two via electrodes.

17. The method of controlling the semiconductor memory device according to claim 12, wherein
a plurality of the plurality of semiconductor layers are provided to be arranged in the second direction.

18. The method of controlling the semiconductor memory device according to claim 12, wherein
the semiconductor memory device comprises a plurality of via insulating layers which are arranged in the second direction along the plurality of conductive layers, and extend in the stacking direction penetrating the plurality of conductive layers.

19. The method of controlling the semiconductor memory device according to claim 12, wherein
the semiconductor memory device comprises a plurality of memory cells each including: a part of one of the plurality of semiconductor layers; one of the plurality of electric charge accumulating layers; and a part of one of the plurality of via electrodes, and
the plurality of memory cells are each configured to store a plurality of bits of data.

20. The method of controlling the semiconductor memory device according to claim 19, wherein
a write operation is performed in order from a memory cell which is far from the plurality of conductive layers, of the plurality of memory cells.
